(19) United States
(12) Patent Application Publication
(10) Pub. No.: US 2016/0056131 A1
(43) Pub. Date: Feb. 25, 2016

(54) SEMICONDUCTOR DEVICE

(71) Applicant: SHARP KABUSHIKI KAISHA, Osaka-shi, Osaka (JP)

(72) Inventors: Tomotoshi SATOH, Osaka-shi (JP); Eiji OGINO, Osaka-shi (JP); Naoyasu IKETANI, Osaka-shi (JP); Satoshi MORISHITA, Osaka-shi (JP)

(73) Assignee: SHARP KABUSHIKI KAISHA, Osaka-shi, Osaka (JP)

(21) Appl. No.: 14/783,118

(22) PCT Filed: Feb. 28, 2014
(86) PCT No.: PCT/JP2014/055079

§ 371 Date: Oct. 8, 2015

(30) Foreign Application Priority Data
May 28, 2013 (JP) 2013-112288

(51) Int. Cl. H01L 25/07; H01L 29/78; H01L 23/495

(52) U.S. Cl. CPC H01L 25/072; H01L 23/49503; H01L 23/49562; H01L 23/49575; H01L 29/7827

(57) ABSTRACT

A primary surface of a normally-off field-effect transistor (102) on which a source electrode (120) is formed and a first primary surface of a die pad (105) are in contact with each other, and the die pad (105) also serves as a source terminal of a semiconductor device (100). Accordingly, a semiconductor device capable of decreasing an inductance, which is a matter of great importance for an operation of a cascode connection circuit, and improving performance of circuit operation is provided.

### TECHNICAL FIELD

The present invention relates to a semiconductor device, and particularly relates to a semiconductor device in which a plurality of field-effect transistors are cascode-connected.

### BACKGROUND ART

A semiconductor device provided with a plurality of field-effect transistors has been conventionally known. As one example thereof, FIG. 9 and FIG. 10 illustrate a conventional semiconductor device 900. FIG. 9 is a side view of the semiconductor device 900 and FIG. 10 is a top view of the semiconductor device 900. As illustrated in FIG. 9 and FIG. 10, the semiconductor device 900 is provided with a normally-on MOSFET (metal-oxide-semiconductor field-effect transistor) 302 and a normally-off MOSFET 303 which are cascode-connected. The normally-on MOSFET 302 is a horizontal device and the normally-off MOSFET 303 is a vertical device.

As illustrated in FIG. 9, the normally-on MOSFET 302 is die-bonded onto a substrate 301 so that a surface of the normally-on MOSFET 302 on which a source terminal 305, a drain terminal 306, and a gate terminal 307 are formed faces upward. Moreover, the normally-off MOSFET 303 is die-bonded onto the substrate 301 so that a surface of the normally-off MOSFET 303 on which a source terminal 310 and a gate terminal 311 are formed faces upward and a surface thereof on which a drain terminal 312 is formed faces downward. The gate terminal 311 of the normally-off MOSFET 303 is bonded to an external lead-out terminal (gate input terminal) 321 through an Al wire 320. In addition, the gate terminal 307 of the normally-on MOSFET 302 is bonded to an external lead-out terminal (GND terminal) 318 through an Al wire 322.

As illustrated in FIG. 10, the source terminal 305 of the normally-on MOSFET 302 is bonded to a terminal 313 of the substrate 301 through an Al wire 315. Note that, the drain terminal 312 of the normally-off MOSFET 303 is electrically connected to the terminal 313. Moreover, the drain terminal 306 of the normally-on MOSFET 302 is bonded to an external lead-out terminal (output terminal) 319 on the substrate 301 through an Al wire 316. The source terminal 310 of the normally-off MOSFET 303 is bonded to the external lead-out terminal (GND terminal) 318 through an Al wire 317.

In the semiconductor device 900, a relatively high parasitic inductance is caused in a cascode connection circuit because of the Al wires 315, 316, 317, 320, and 322. As a result, there is a problem that an impedance of an entire circuit becomes high. Further, in the semiconductor device 900, the normally-on MOSFET 302 and the normally-off MOSFET 303 are arranged side by side on the substrate 301, so that the substrate 301 needs to have a large area. Thus, there is a problem that the semiconductor device 900 is difficult to be incorporated in equipment or the number thereof allowed to be mounted on equipment is small.

On the other hand, PTL 1 discloses a semiconductor device provided with a first semiconductor chip and a second semiconductor chip. In the semiconductor device, the first semiconductor chip and the second semiconductor chip are stacked on a substrate and bonded to an electrode of the substrate by flip chip bonding through conductive bumps, so that an inductance of a circuit is decreased.

When a circuit of the semiconductor device described in PTL 1 operates, inductance is a matter of importance at portions where the first semiconductor chip and the second semiconductor chip are connected to the substrate and an external connection terminal. However, the first semiconductor chip and the second semiconductor chip in the circuit are connected to the substrate and the external connection terminals through the conductive bumps. Because the inductance of the conductive bumps is large, the semiconductor device has a problem that the inductance which is a matter of importance for the operation of the circuit is not able to be decreased sufficiently.

### CITATION LIST

### Patent Literature

PTL 1: Japanese Unexamined Patent Application Publication No. 2011-54652 (Published on Mar. 17, 2011)

### SUMMARY OF INVENTION

### Technical Problem

The invention has been made in view of the aforementioned problems, and aims to provide a semiconductor device or the like that is capable of decreasing an inductance, which is a matter of great importance for the operation of a cascode connection circuit, and improving performance of circuit operation.

### Solution to Problem

In order to solve the aforementioned problem, a semiconductor device according to one aspect of the invention is a semiconductor device in which a plurality of field-effect transistors are cascode-connected, including a normally-off field-effect transistor as one of the plurality of field-effect transistors, which has a first primary surface on which a gate electrode and a drain electrode are formed and a second primary surface on which a source electrode is formed; and a die pad which has a first primary surface in contact with the second primary surface of the normally-off field-effect transistor and serves as a source terminal of the semiconductor device.

### Advantageous Effects of Invention

According to the one aspect of the invention, it is possible to decrease an inductance, which is a matter of great importance for an operation of a cascode connection circuit, and improve performance of circuit operation.

### BRIEF DESCRIPTION OF DRAWINGS

FIG. 1 is a plan view illustrating a configuration of a semiconductor device according to one embodiment of the invention.

FIG. 2 is a side view of the semiconductor device illustrated in FIG. 1.

FIG. 3 is a circuit diagram of the semiconductor device illustrated in FIG. 1.

FIG. 4 is a plan view illustrating a configuration of a semiconductor device according to another embodiment of the invention.

FIG. 5 is a plan view illustrating a configuration of a semiconductor device according to another embodiment of the invention.

FIG. 6 is a side view of the semiconductor device illustrated in FIG. 5.

FIG. 7 is a plan view illustrating a configuration of a semiconductor device according to another embodiment of the invention.

FIG. 8 is a cross-sectional view of electronic equipment provided with the semiconductor device illustrated in FIG. 1.

FIG. 9 is a side view illustrating a configuration of a semiconductor device of the related art.

FIG. 10 is a plan view of the semiconductor device of the related art illustrated in FIG. 9.

### DESCRIPTION OF EMBODIMENTS

### Embodiment 1

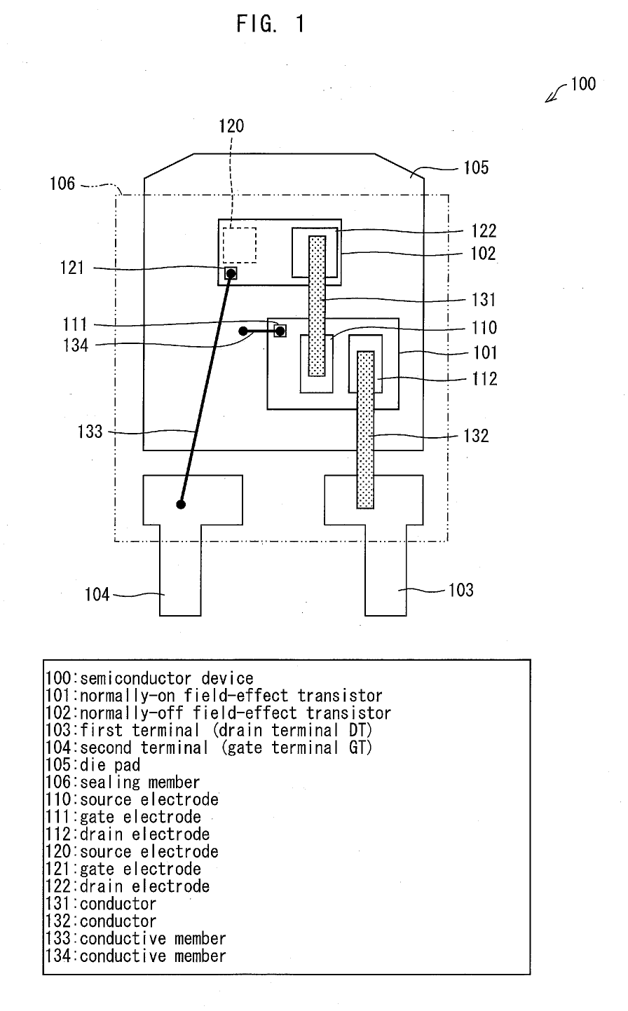

One embodiment of the invention will be described below in detail by using FIG. 1 to FIG. 3.

### (Configuration of Semiconductor Device 100)

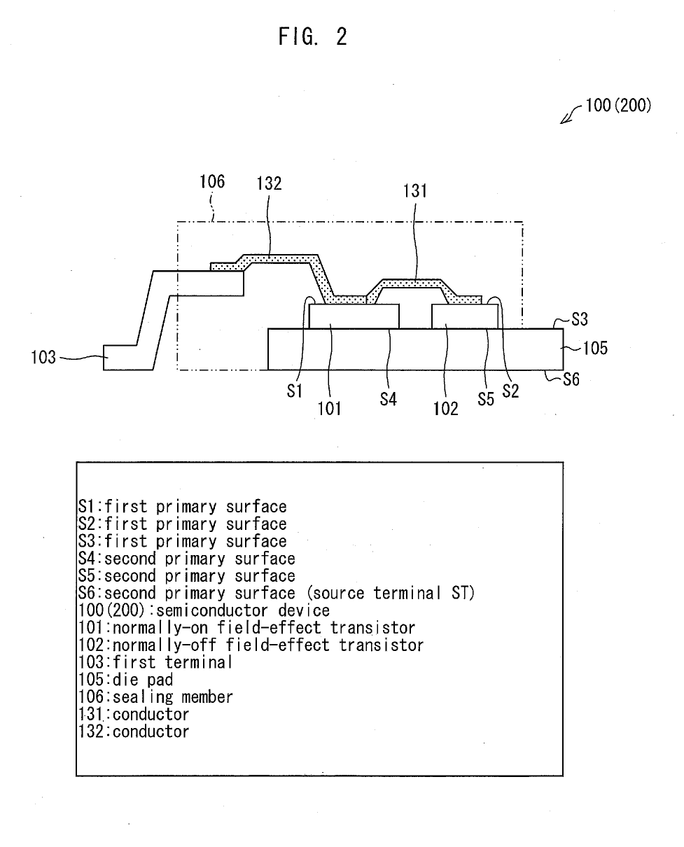

First, a configuration of a semiconductor device 100 according to the present embodiment will be described by using FIG. 1 and FIG. 2. FIG. 1 and FIG. 2 are a plan view and a side view of the semiconductor device 100. Note that, a conductive member 133, a conductive member 134 and a second terminal 104 are not illustrated in FIG. 2.

As illustrated in FIG. 1, the semiconductor device 100 is provided with a normally-on field-effect transistor 101 (hereinafter, simply referred to as a transistor 101), a normally-off field-effect transistor 102 (hereinafter, simply referred to as a transistor 102), a first terminal 103 (drain terminal DT), the second terminal 104 (gate terminal GT), a die pad 105, and a sealing member 106. The transistor 101 has a breakdown voltage higher than that of the transistor 102. The transistor 101 may be, for example, a GaN-MOSFET. The transistor 102 may be, for example, a Si-MOSFET. The die pad 105 merely needs to be formed of a material having conductivity and is not limited by other conditions. Moreover, the sealing member 106 is formed of, for example, a resin.

As illustrated in FIG. 2, the transistor 101 and the transistor 102 are cascode-connected in the semiconductor device 100. The transistor 101 and the transistor 102 are arranged on the die pad 105 and sealed by the sealing member 106. A part of a lower surface of the die pad 105 also serves as a source terminal ST of the semiconductor device 100. Hereinafter, an upper surface and a lower surface of the transistor 101 are referred to as a first primary surface S1 and a second primary surface S4, respectively. An upper surface and a lower surface of the transistor 102 are referred to as a first primary surface S2 and a second primary surface S5, respectively. An upper surface and the lower surface of the die pad 105 are referred to as a first primary surface S3 and a second primary surface S6, respectively.

As illustrated in FIG. 1, a source electrode 110, a gate electrode 111, and a drain electrode 112 are arranged on the first primary surface S1 of the transistor 101. A gate electrode 121 and a drain electrode 122 are arranged on the first primary surface S2 of the transistor 102. Further, a source electrode 120 is arranged on the second primary surface S5 of the transistor 102. Note that, for convenience of description, FIG. 1 is illustrated so that the source electrode 120 is formed on a part of the rear surface (second primary surface S5) of the transistor 102, but a case where the entire rear surface of the transistor 102 serves as the source electrode 120 is not departed from a gist of the invention.

The source electrode 110 which is arranged on the first primary surface S1 of the transistor 101 and the drain electrode 122 which is arranged on the first primary surface S2 of the transistor 102 are electrically connected by a conductor 131. The drain electrode 112 which is arranged on the first primary surface of the transistor 101 and the first terminal 103 are electrically connected by a conductor 132.

The gate electrode 121 which is arranged on the first primary surface S2 of the transistor 102 and the second terminal 104 are electrically connected by the conductive member 133. The gate electrode 111 which is arranged on the first primary surface S1 of the transistor 101 and the first primary surface S3 of the die pad 105 are electrically connected by the conductive member 134. Further, the source electrode 120 on the second primary surface S5 of the transistor 102 and the first primary surface S3 of the die pad 105 are electrically connected.

As illustrated in FIG. 2, the first primary surface S3 of the die pad 105 and the second primary surface S5 of the transistor 102 in the semiconductor device 100 are opposed and in contact with each other. Further, the first primary surface S3 of the die pad 105 and the second primary surface S4 of the transistor 101 are opposed and in contact with each other.

The second primary surface S4 of the transistor 101 is die-bonded onto the first primary surface S3 of the die pad 105 with a solder or the like. The solder has a function of die-bonding the transistor 101 to the die pad 105 and also a function of electrically connecting the transistor 101 and the die pad 105. Note that, a conductive paste having high die-bonding performance may be used instead of the solder. The second primary surface S5 of the transistor 102 is die-bonded onto the first primary surface S3 of the die pad 105 by using a thermally conductive die-bonding material. When the die-bonding material has thermal conductivity, heat generated at the transistor 102 is able to be radiated to the die pad 105. Note that, the transistor 102 and the die pad 105 do not need to be electrically connected, so that the die-bonding member may not have conductivity.

### (About Circuit EC of Semiconductor Device 100)

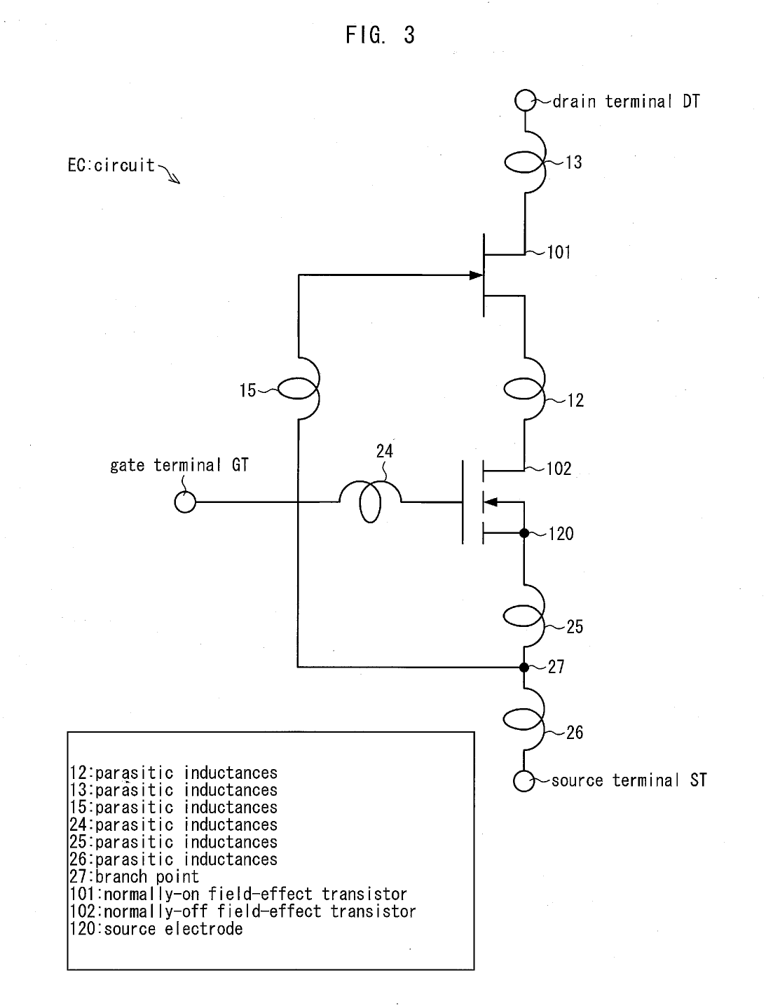

Next, a configuration and an operation of an electronic circuit EC formed in the semiconductor device 100 will be described by using FIG. 3. FIG. 3 is a circuit diagram of the circuit EC. As illustrated in FIG. 3, the circuit EC includes the transistor 101, the transistor 102, the drain terminal DT (that is, the first terminal 103), the gate terminal GT (that is, the second terminal 104), and the source terminal ST (that is, the second primary surface S6 of the die pad 105).

In the circuit EC, parasitic inductances 12, 13, 15, 24, 25, and 26 are inductances which are caused to be parasitic in the circuit EC when respective elements are electrically connected to each other for forming the circuit EC. That is, in FIG. 3, the parasitic inductances 12, 13, 15, 24, 25, and 26 are represented schematically by using circuit symbols of a coil, which is not a coil actively put in the circuit EC. The parasitic inductances 12, 13, 15, 24, 25, and 26 generally have almost from 1 nanohenry to less than 20 nanohenries. Each of the parasitic inductances 12, 13, 15, 24, 25, and 26 will be described in detail below.

The parasitic inductance 12 is an inductance of the conductor 131 which connects the source electrode 110 of the transistor 101 and the drain electrode 122 of the transistor 102. Moreover, the parasitic inductance 13 is an inductance of the conductor 132 which electrically connects the drain electrode 112 of the transistor 101 and the first terminal 103 (drain terminal DT). The parasitic inductance 15 is an inductance of the conductive member 134 which electrically connects the gate electrode 111 of the transistor 101 and a branch point 27. Here, the branch point 27 is a point at which the circuit EC branches to a current path which passes through the source electrode 120 of the transistor 102, the gate electrode 111 of the transistor 101, or the second primary surface S6 (source terminal ST) of the die pad 105. The branch point 27 exists on the first primary surface S3 of the die pad 105.

The parasitic inductance 24 is an inductance of the conductive member 133 which electrically connects the gate electrode 121 of the transistor 102 and the second terminal 104 (gate terminal GT). The parasitic inductance 25 is an inductance at a portion where the second primary surface S5 of the transistor 102 and the first primary surface S3 of the die pad 105 are connected. The parasitic inductance 26 is an inductance between the second primary surface S6 (source terminal ST) of the die pad 105 and the branch point 27.

In the circuit EC, current mainly flows from the drain terminal DT to the source terminal 5 via the parasitic inductance 13, the transistor 101, the parasitic inductance 12, the transistor 102, the parasitic inductance 25, the branch point 27, and the parasitic inductance 26 in this order.

### (Suppression of Parasitic Inductances in Circuit EC)

A counter electromotive voltage which is caused in the circuit EC by the parasitic inductances 12, 13, 15, 25, and 26 is obtained by multiplying a value of each of the parasitic inductances by a change rate of the current. Therefore, as the change rate of the aforementioned main current increases, a counter electromotive force generated in the circuit EC by the parasitic inductances 12, 13, 15, 25, and 26 increases in the circuit EC. For example, when a current of 100 A flows through the circuit EC as a rectangular wave signal of around 1 MHz, there is a change of 100 A per 10 nanoseconds in the circuit EC. That is, the change rate of the current in the circuit EC becomes 10¹⁰ A/second. In this case, even when the parasitic inductances 12, 13, 25, and 26 are mere 1 nanohenry, a counter electromotive force of 10 V is to be caused in the circuit EC. Such a large counter electromotive force may have an influence on an operation of the circuit EC.

The transistor 102 is mainly in charge of control of the semiconductor device 100. Thus, the counter electromotive force applied to the source electrode 120 of the transistor 102 has a particularly great influence on the operation of the circuit EC. This counter electromotive force is caused in the parasitic inductances 25 and 26 (refer to FIG. 3). The counter electromotive force caused in the parasitic inductances 25 and 26 acts so as to substantially reduce a voltage applied to the gate electrode 121 of the transistor 102. Thus, when the counter electromotive force caused by the parasitic inductances 25 and 26 reaches a threshold, on-off of the transistor 102 is inverted. As a result thereof, the circuit EC is to erroneously operate. Accordingly, the change rate of the current in the circuit EC needs to be controlled so that the counter electromotive force caused at the parasitic inductances 25 and 26 does not exceed the threshold of the transistor 102.

Meanwhile, as described above, the source electrode 120 which is arranged on the second primary surface S5 of the transistor 102 is in contact with the first primary surface S3 of the die pad 105 in the semiconductor device 100. Further, (a part of) the second primary surface S6 of the die pad 105 serves as the source terminal ST of the semiconductor device 100. Thus, the parasitic inductance 25 is an inductance which is caused at the portion where the second primary surface S5 of the transistor 102 and the first primary surface S3 of the die pad 105 are connected. The parasitic inductance 26 is an inductance which is caused between the first primary surface S3 and the second primary surface S6 of the die pad 105.

Accordingly, the parasitic inductance 25 and the parasitic inductance 26 are determined from a thickness of the portion where the second primary surface S5 of the transistor 102 and the first primary surface S3 of the die pad 105 are connected and a thickness of the die pad 105. The parasitic inductances 25 and 26 are almost proportional to a distance for which the current flows. Since both of the thickness of the portion and the thickness of the die pad 105 are sufficiently small as compared to a length of the semiconductor device 100 in a direction parallel to the first primary surface S3 of the die pad 105 (hereinafter, referred to as a reference direction), the parasitic inductance 25 and the parasitic inductance 26 are also small. Thus, the counter electromotive force which is generated in the parasitic inductance 25 and the parasitic inductance 26 and applied to the source electrode 120 of the transistor 102 is small, so that on-off of the transistor 102 is less likely to be inverted by the counter electromotive force. Accordingly, the circuit EC is able to operate stably.

As described above, the counter electromotive force caused in the parasitic inductances 25 and 26 is applied to the source electrode 120 of the transistor 102. On the other hand, a counter electromotive force caused in the parasitic inductances 15 and 26 is applied to the gate electrode 111 of the transistor 101. As described above, the parasitic inductance 15 is an inductance between the gate electrode 111 of the transistor 101 and the branch point 27. On the other hand, the parasitic inductance 25 is an inductance at the portion where the second primary surface S5 of the transistor 102 and the first primary surface S3 of the die pad 105 are connected. As is clear from FIG. 1 and FIG. 2, a length from the gate electrode 111 to the branch point 27 (that is, a length of the conductor 134) is longer than a length from the second primary surface S5 of the transistor 102 to the first primary surface S3 of the die pad 105. Therefore, the counter electromotive force caused in the parasitic inductance 15 is more likely to be larger than the counter electromotive force caused in the parasitic inductance 25. Accordingly, the counter electromotive force applied to the gate electrode 111 of the transistor 101 is more likely to be larger than the counter electromotive force applied to the source electrode 120 of the transistor 102. Thus, it is desired that the breakdown voltage of the transistor 101 is larger than the breakdown voltage of the transistor 102 so that on-off of the transistor 101 is not inverted due to the counter electromotive force.

### Embodiment 2

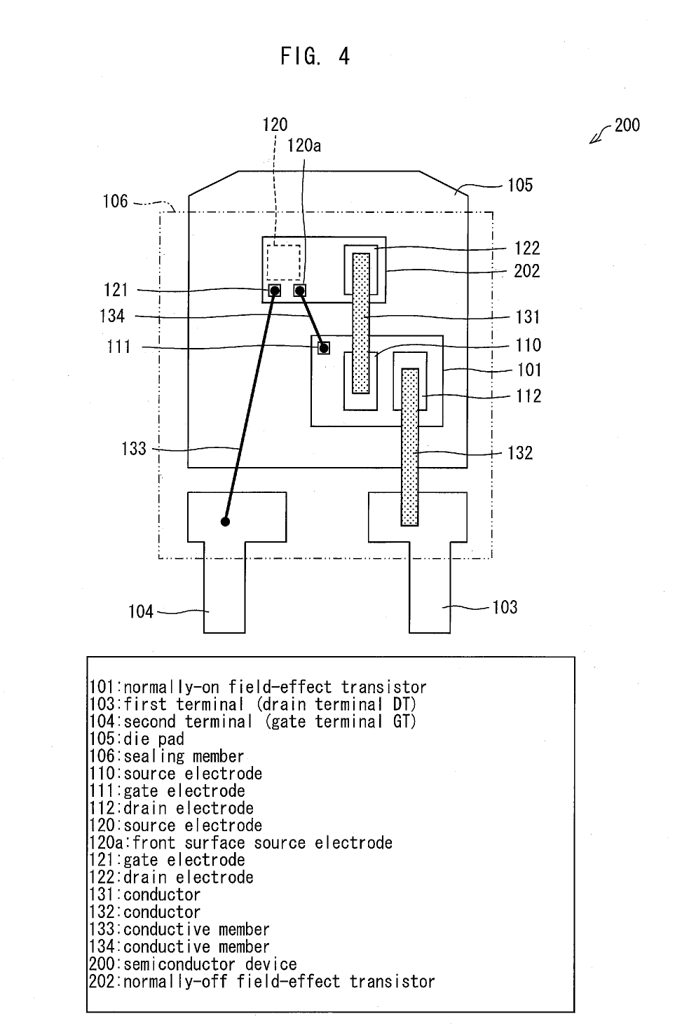

Another embodiment of the invention will be described based on FIG. 4 as follows. Note that, for convenience of description, the same reference signs are assigned to members having the same functions as those of the members described in the aforementioned embodiment and description thereof will be omitted.

### (Configuration of Semiconductor Device 200)

A configuration of a semiconductor device 200 according to the present embodiment will be described below by using FIG. 4. FIG. 4 is a plan view of the semiconductor device 200. Note that, the configuration of the semiconductor device 200 in a side view is similar to the configuration of the semiconductor device 100 illustrated in FIG. 2.

As illustrated in FIG. 4, the semiconductor device 200 is provided with a normally-off field-effect transistor 202 (hereinafter, referred to as a transistor 202) instead of the normally-off field-effect transistor 102 in the configuration of the semiconductor device 100 in the aforementioned embodiment. Moreover, a member which is wired by the conductive member 134 is different between the semiconductor device 200 and the semiconductor device 100. Other configuration of the semiconductor device 200 is similar to that of the semiconductor device 100. Further, an electric circuit formed in the semiconductor device 200 is similar to the circuit EC of the semiconductor device 100 illustrated in FIG. 3.

As illustrated in FIG. 4, a front surface source electrode 120a is provided on the first primary surface S2 of the transistor 202. The front surface source electrode 120a on the first primary surface S2 of the transistor 202 is electrically connected to the source electrode 120 on the second primary surface S5 of the transistor 202. The branch point 27 (refer to FIG. 3) among the gate electrode 111 of the transistor 101, the source electrode 120 of the transistor 202, and the second primary surface S6 (source terminal ST) of the die pad 105 exists inside the transistor 202.

### (About Circuit EC of Semiconductor Device 200)

According to the configuration of the semiconductor device 200, the parasitic inductance 25 depends on a thickness of the die pad 105, which extends from the second primary surface S6 of the die pad 105 to the branch point 27, and a thickness of the transistor 202. Moreover, the parasitic inductance 26 depends on a thickness of the portion where the second primary surface S5 of the transistor 202 and the die pad 105 are connected, in addition to a thickness of the transistor 202, which extends from the branch point 27 to the first primary surface S3 of the die pad 105.

Similarly to the semiconductor device 100 of the aforementioned embodiment, both of the thickness of the portion described above and the thickness of the die pad 105 are sufficiently small as compared to a length of the semiconductor device 200 in the reference direction. Moreover, the thickness of the transistor 202 is also sufficiently small as compared to the length of the semiconductor device 200 in the reference direction. Thus, the parasitic inductance 25 and the parasitic inductance 26 are also small.

As described above, since the parasitic inductances 25 and 26 are small in the semiconductor device 200, a counter electromotive force caused in the circuit EC is small. Accordingly, the circuit EC of the semiconductor device 200 is able to operate stably.

### Embodiment 3

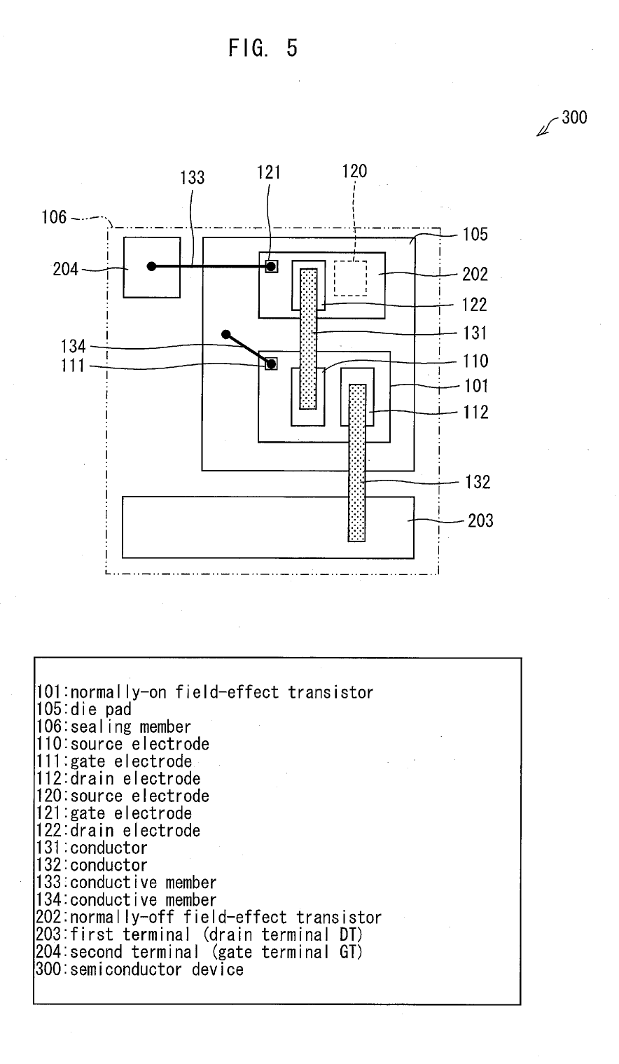

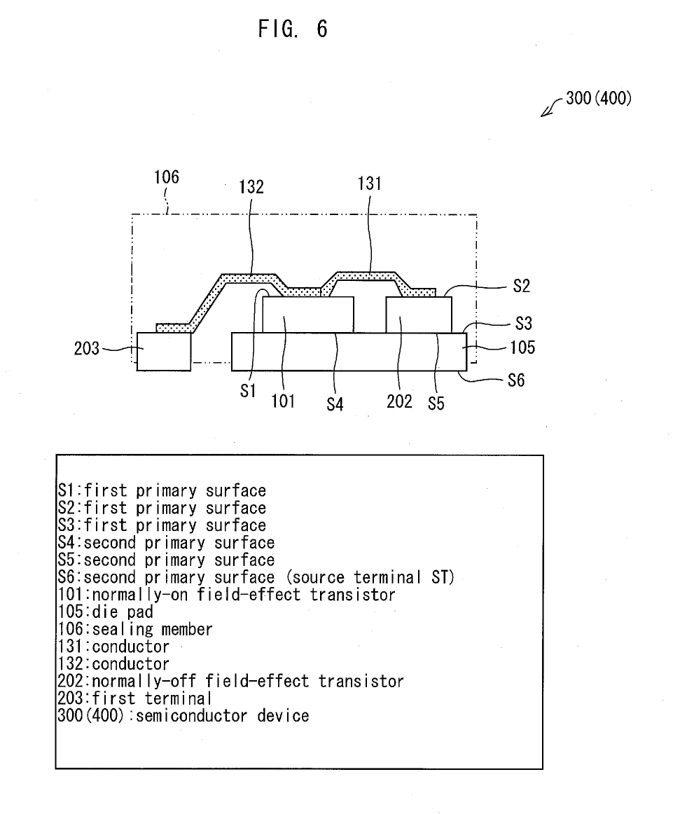

Another embodiment of the invention will be described based on FIG. 5 and FIG. 6 as follows. Note that, for convenience of description, the same reference signs are assigned to members having the same functions as those of the members described in the aforementioned embodiments and description thereof will be omitted.

### (Configuration of Semiconductor Device 300)

A configuration of a semiconductor device 300 according to the present embodiment will be described by using FIG. 5 and FIG. 6. FIG. 5 and FIG. 6 are a plan view and a side view of the semiconductor device 300. Note that, the conductive member 133, the conductive member 134, and a second terminal 204 are not illustrated in FIG. 6.

As illustrated in FIG. 5, a mounting structure of a package of the semiconductor device 300 is different from that of the semiconductor device 100 in the aforementioned embodiment. Specifically, the semiconductor device 300 is provided with a first terminal 203 (drain terminal DT) and the second terminal 204 (gate terminal GT) instead of the first terminal 103 and the second terminal 104 in the configuration of the semiconductor device 100. Other configuration of the semiconductor device 300 is similar to that of the semiconductor device 100. Further, an electric circuit formed in the semiconductor device 300 is similar to the circuit EC of the semiconductor device 100 illustrated in FIG. 3.

As illustrated in FIG. 5, the first terminal 203 and the second terminal 204 have a different positional relation with respect to each element on the die pad 105 from that of the first terminal 103 and the second terminal 104. Moreover, as illustrated in FIG. 5 and FIG. 6, a shape of the first terminal 203 is different from a shape of the first terminal 103 of the semiconductor device 100 (refer to FIG. 1 and FIG. 2). Note that, positions of the first terminal 203 and the second terminal 204 may be defined based on the positions of the transistor 101 and the transistor 202 on the die pad 105, and positions of the respective elements on the transistor 101 and the transistor 102. Specifically, the positions of the first terminal 203 and the second terminal 204 may be defined so that parasitic inductances of the circuit EC of the semiconductor device 300 become small as described below.

As illustrated in FIG. 5, a distance between the second terminal 204 and the gate electrode 121 in the semiconductor device 300 is shorter than a distance between the second terminal 104 and the gate electrode 121 in the semiconductor device 100. Therefore, a length of the conductive member 133 which connects the second terminal 204 and the gate electrode 121 is shorter than a length of the conductive member 133 in the semiconductor device 100. Note that, as illustrated in FIG. 6, a length of the conductor 132 which connects the first terminal 203 and the drain electrode 112 is also different from a length of the conductor 132 in the semiconductor device 100.

### (About Circuit EC of Semiconductor Device 300)

According to the configuration of the semiconductor device 300, it is possible to shorten the length of the conductive member 133 compared to that of the configuration of the semiconductor device 100. Accordingly, the parasitic inductance 24 which depends on the length of the conductive member 133 becomes small.

As described above, the parasitic inductance 24 of the semiconductor device 300 is smaller than the parasitic inductance 24 of the semiconductor device 100. Further, similarly to the semiconductor device 100 of the aforementioned embodiment, the parasitic inductance 25 and the parasitic inductance 26 are small in the semiconductor device 300. Accordingly, since a counter electromotive force caused in the circuit EC of the semiconductor device 300 is small, the circuit EC of the semiconductor device 300 is able to operate stably.

As illustrated in FIG. 6, in the semiconductor device 300, the first terminal 203 is gathered on a lower surface side of the semiconductor device 300. Further, though not illustrated, the second terminal 204 is also gathered on the lower surface side of the semiconductor device 300. Thus, a distance between the first terminal 203 and the drain electrode 112 and the distance between the second terminal 204 and the gate electrode 121 are able to be shortened in the configuration of the semiconductor device 300 compared to the configurations of the semiconductor devices 100 and 200. Accordingly, (i) the lengths of the conductor 132 and the conductive member 133 are able to be shortened, thus causing the parasitic inductances 13 and 24 which depend on these lengths to be reduced. Further, (ii) it is possible to reduce a size of the semiconductor device 300.

Though the first terminal 103 extends in a direction orthogonal to a side surface of the die pad 105 (direction away from the die pad 105) in the semiconductor device 100, the first terminal 203 extends in a direction parallel to the side surface of the die pad 105 in the semiconductor device 300. Thus, it is possible to reduce the size of the semiconductor device 300 compared to the semiconductor device 100.

For example, when the semiconductor device 100 has the size of 7 mm×9 mm, the semiconductor device 300 has the size of 7 mm×6 mm (though the first terminal 103 and the second terminal 104 extend to the outside of the sealing member 106 in the semiconductor device 100, the first terminal 203 and the second terminal 204 are accommodated inside the sealing member 106 in the semiconductor device 300).

### Embodiment 4

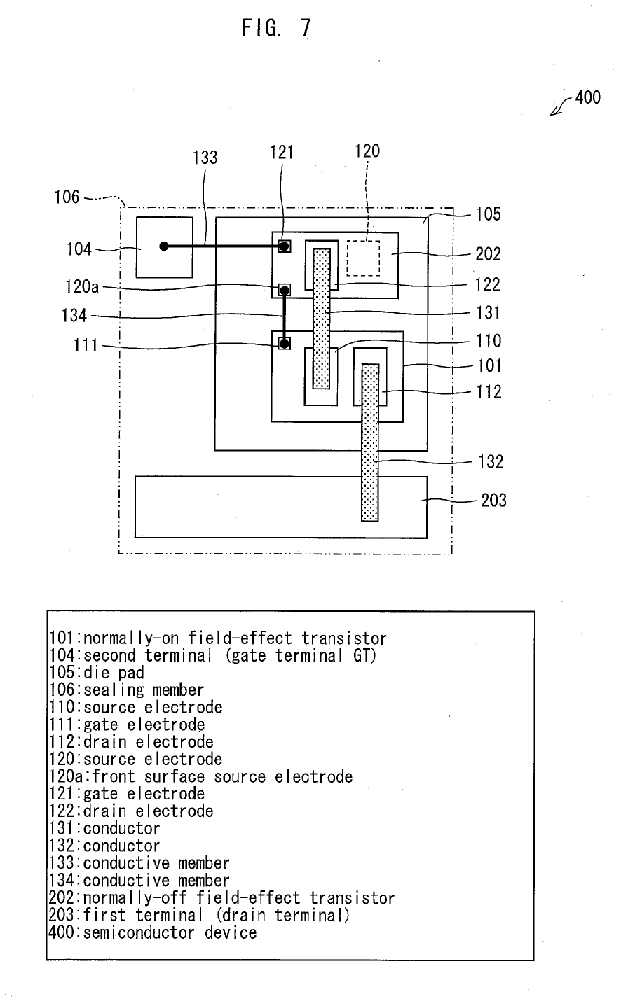

Another embodiment of the invention will be described based on FIG. 7 as follows. Note that, for convenience of description, the same reference signs are assigned to members having the same functions as those of the members described in the aforementioned embodiments and description thereof will be omitted.

### (Configuration of Semiconductor Device 400)

Here, a configuration of a semiconductor device 400 according to the present embodiment will be described by using FIG. 7. FIG. 7 is a plan view of the semiconductor device 400. Not that, the configuration of the semiconductor device 400 in a side view is similar to the configuration of the semiconductor device 300 illustrated in FIG. 6.

As illustrated in FIG. 7, the semiconductor device 400 is provided with a normally-off field-effect transistor 202 (hereinafter, referred to as a transistor 202) instead of the normally-off field-effect transistor 102 in the configuration of the semiconductor device 300 in the aforementioned embodiment. Moreover, a member which is wired by the conductive member 134 is different between the semiconductor device 400 and the semiconductor device 300. Other configuration of the semiconductor device 400 is similar to that of the semiconductor device 300. Further, an electric circuit formed in the semiconductor device 400 is similar to the circuit EC of the semiconductor device 100 illustrated in FIG. 3.

As illustrated in FIG. 7, the front surface source electrode 120a is provided on a top surface (first primary surface S2) of the transistor 202. The branch point 27 (refer to FIG. 3) among the gate electrode 111 of the transistor 101, the source electrode 120 of the transistor 102, and the second primary surface S6 (source terminal ST) of the die pad 105 exists inside the transistor 202.

### (About Circuit EC of Semiconductor Device 400)

According to the configuration of the semiconductor device 400, similarly to the configuration of the semiconductor device 200 in the aforementioned embodiment, the parasitic inductance 25 depends on a thickness of the die pad 105, which extends from the second primary surface S6 of the die pad 105 to the branch point 27, and a thickness of the transistor 202. Moreover, the parasitic inductance 26 depends on a thickness of the portion where the second primary surface S5 of the transistor 202 and the die pad 105 are connected, in addition to a thickness of the die pad 105, which extends from the branch point 27 to the first primary surface S3 of the die pad 105. Further, according to the configuration of the semiconductor device 400, the length of the conductive member 133 is short similarly to the configuration of the semiconductor device 300 in the aforementioned embodiment.

Accordingly, the parasitic inductance 25 and the parasitic inductance 26 of the semiconductor device 400 are small similarly to the parasitic inductance 25 and the parasitic inductance 26 of the semiconductor device 200. Further, the parasitic inductance 24 of the semiconductor device 400 is small similarly to the parasitic inductance 24 of the semiconductor device 300 in the aforementioned embodiment.

As described above, since the parasitic inductances 24, 25, and 26 are small in the semiconductor device 400, a counter electromotive force caused in the circuit EC is small. Accordingly, the circuit EC of the semiconductor device 400 is able to operate stably.

### Embodiment 5

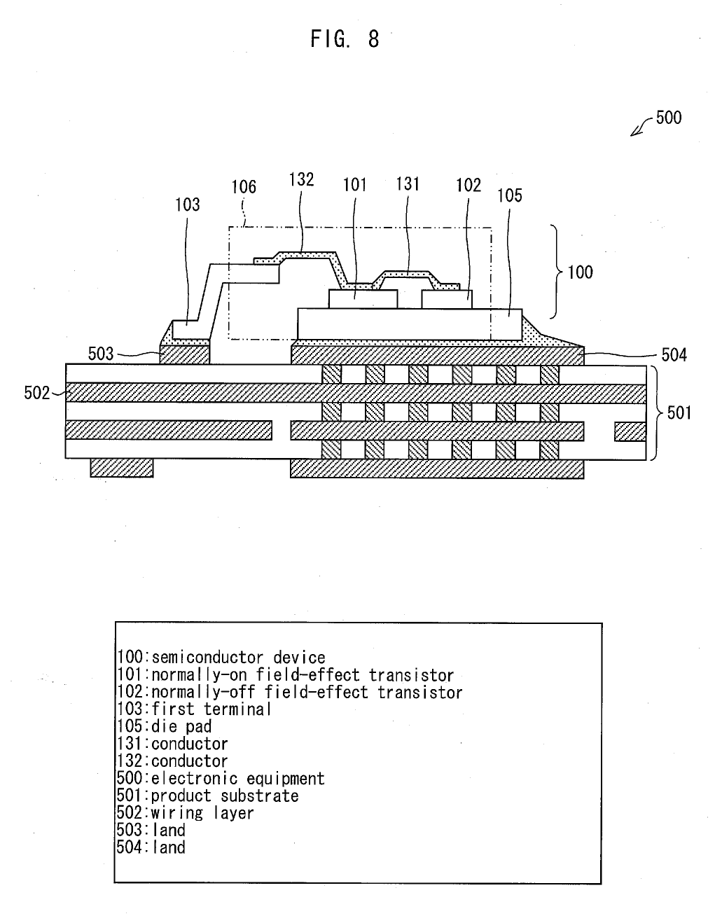

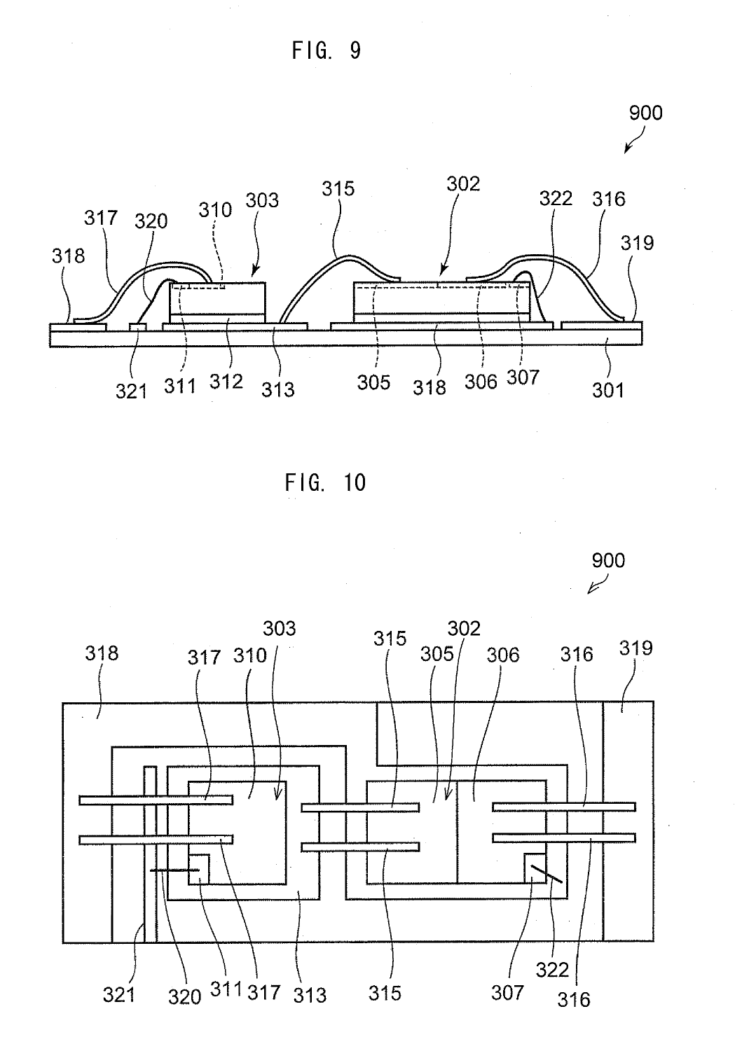

Another embodiment of the invention will be described based on FIG. 8 as follows. Note that, for convenience of description, the same reference signs are assigned to members having the same functions as those of the members described in the aforementioned embodiments and description thereof will be omitted.

### (Configuration of Electronic Equipment 500)

A configuration of electronic equipment 500 according to the present embodiment will be described below by using FIG. 8. FIG. 8 is a side view of the electronic equipment 500. The electronic equipment 500 is provided with the semiconductor device 100 of the aforementioned embodiment and a product substrate 501. In the electronic equipment 500, the semiconductor device 100 is mounted on the product substrate 501. Note that, the electronic equipment 500 may be provided with the semiconductor device 200, 300, or 400 instead of the semiconductor device 100.

As illustrated in FIG. 8, a wiring layer 502 which has the same potential as that of the source terminal ST of the semiconductor device 100 is formed on the product substrate 501. Moreover, a land 504 which is connected to the second primary surface S6 (source terminal ST) of the die pad 105 and a land 503 which is connected to the first terminal 103 (drain terminal DT) are formed on the product substrate 501.

The parasitic inductances 25 and 26 which cause the counter electromotive force to be applied to the source electrode 120 which is arranged on the second primary surface S5 of the transistor 102 (refer to FIG. 1 and FIG. 2) depend on a distance from the source electrode 120 to the source terminal ST, that is, the thickness of the die pad 105. Since the thickness of the die pad 105 is sufficiently small as compared to the length of the semiconductor device 100 in the reference direction, the parasitic inductances 25 and 26 which depend on the thickness are also small. Note that, when the electronic equipment 500 is provided with the semiconductor device 300 instead of the semiconductor device 100, the parasitic inductances 25 and 26 depend on not only the thickness of the die pad 105 but also the thickness of the normally-off field-effect transistor 102. As described in the aforementioned embodiment, the parasitic inductances 25 and 26 are small even in the case of such a configuration.

As described above, since the parasitic inductances 25 and 26 of the semiconductor device 100 are small, the counter electromotive force which is caused in the circuit EC of the semiconductor device 100 is small. Accordingly, the circuit EC of the semiconductor device 100 is able to operate stably. Therefore, it is possible to provide the electronic equipment 500 with less malfunction.

### [Conclusion]

Each of the semiconductor devices (100, 200, 300, and 400) according to an aspect 1 of the invention is a semiconductor device in which a plurality of field-effect transistors are cascode-connected, including: a normally-off field-effect transistor (102) as one of the plurality of field-effect transistors, which has a first primary surface (S2) on which a gate electrode (121) and a drain electrode (122) are formed and a second primary surface (S5) on which a source electrode (120) is formed; and a die pad (105) which has a first primary surface (S3) in contact with the second primary surface of the normally-off field-effect transistor and also serves as a source terminal of the semiconductor device.

According to the aforementioned configuration, the second primary surface of the normally-off field-effect transistor and the first primary surface of the die pad are in contact with each other. The source electrode is formed on the second primary surface of the normally-off field-effect transistor and the first primary surface of the die pad also serves as the source terminal. Therefore, the source electrode of the normally-off field-effect transistor and the source terminal are electrically connected thorough the die pad having conductivity.

With the connection, the source electrode of the normally-off field-effect transistor is able to reach the source terminal only with an inductance of a part held between the first primary surface and the second primary surface of the die pad. Accordingly, with the aforementioned configuration, it is possible to decrease the inductance, which is a matter of great importance for an operation of a cascode connection circuit, and improve performance of circuit operation. The effect of the invention will be described in more detail as follows.

A parasitic inductance which is caused at a portion where the second primary surface of the transistor and the die pad are connected and a parasitic inductance which is caused between the first primary surface and the second primary surface of the die pad are determined from a thickness of the portion and a thickness of the die pad. Here, the parasitic inductances are almost proportional to a distance for which current flows. Since both of the thickness of the portion and the thickness of the die pad are sufficiently small as compared to a length of the semiconductor device in a reference direction, the parasitic inductances described above are also small.

In this manner, since the parasitic inductance which is caused at the portion where the second primary surface of the transistor and the die pad are connected and the parasitic inductance which is caused between the first primary surface and the second primary surface of the die pad are small, a counter electromotive force caused in the circuit of the semiconductor device due to the parasitic inductances is small. Accordingly, the circuit of the semiconductor device is able to operate stably.

Note that, the second primary surface of the normally-off field-effect transistor and the first primary surface of the die pad may be in contact with each other through a die-bonding material or an adhesive material such as a solder.

Each of the semiconductor devices (200 and 400) according to an aspect 2 of the invention may be configured to further include in the aspect 1 a normally-on field-effect transistor (101) as another one of the plurality of field-effect transistors, which has a first primary surface (S1) on which a source electrode (110), a gate electrode (111), and a drain electrode (112) are formed, in which a source electrode (front surface source electrode 120a) is formed not only on the second primary surface (S5) but also on the first primary surface (S2) of the normally-off field-effect transistor (102), and the source electrode which is formed on the first primary surface of the normally-off field-effect transistor and the gate electrode which is formed on the first primary surface of the normally-on field-effect transistor are connected by a conductive member (134).

According to the aforementioned configuration, a length of the conductive member which connects the source electrode of the normally-off field-effect transistor and the gate electrode of the normally-on field-effect transistor is able to be shortened. As a result thereof, parasitic inductances which depend on the length of the conductive member are able to be decreased. This is because the parasitic inductances are almost proportional to a distance for which current flows.

The semiconductor device according to an aspect 3 of the invention may be configured in the aspect 2 such that the normally-on field-effect transistor (101) has a breakdown voltage higher than that of the normally-off field-effect transistor (102 or 202).

According to the aforementioned configuration, even when a counter electromotive force applied to the gate electrode of the normally-on transistor is larger than a counter electromotive force applied to the source electrode of the normally-off transistor, on-off of the normally-on transistor is less likely to be inverted. Therefore, the circuit of the semiconductor device is able to operate more stably.

The invention is not limited to each of the embodiments described above and can be modified variously within the scope defined by the claims, and embodiments obtained by appropriately combining technical means disclosed in different embodiments are also included in the technical scope of the invention. Further, by combining the technical means disclosed in each of the embodiments, a new technical feature may be formed.

### INDUSTRIAL APPLICABILITY

The invention is able to be used for a semiconductor device and electronic equipment provided with the semiconductor device.

### REFERENCE SIGNS LIST

100, 200, 300, 400 semiconductor device
101 normally-on field-effect transistor
102, 202 normally-off field-effect transistor
103 first terminal (drain terminal DT)
104 second terminal (gate terminal GT)
S6 second primary surface (third terminal; source terminal ST)
134 conductive member

1. A semiconductor device in which a plurality of field-effect transistors are cascode-connected, comprising:
a normally-off field-effect transistor as one of the plurality of field-effect transistors, which has a first primary surface on which a gate electrode and a drain electrode are formed and a second primary surface on which a source electrode is formed; and
a die pad which has a first primary surface in contact with the second primary surface of the normally-off field-effect transistor and serves as a source terminal of the semiconductor device; and
a normally-on field-effect transistor as another one of the plurality of field-effect transistors, which has a first primary surface on which a source electrode, a gate electrode, and a drain electrode are formed, wherein
a source electrode is formed not only on the second primary surface but also on the first primary surface in the normally-off field-effect transistor, and
the source electrode which is formed on the first primary surface of the normally-off field-effect transistor and the gate electrode which is formed on the first primary surface of the normally-on field-effect transistor are connected by a conductive member.

2. (canceled)

3. The semiconductor device according to claim 1, wherein the normally-on field-effect transistor has a breakdown voltage higher than a breakdown voltage of the normally-off field-effect transistor.
